(19) United States
(12) Patent Application Publication
(10) Pub. No.: US 2026/0066619 A1
(43) Pub. Date: Mar. 5, 2026

(54) VCSEL ARRAY WITH IMPROVED OPTICAL PROPERTIES

(71) Applicant: Korea Photonics Technology Institute, Gwangju (KR)

(72) Inventor: Keon Hwa LEE, Gwangju (KR)

(73) Assignee: Korea Photonics Technology Institute, Gwangju (KR)

(21) Appl. No.: 19/384,054

(22) Filed: Nov. 10, 2025

Related U.S. Application Data
(62) Division of application No. 17/989,803, filed on Nov. 18, 2022.

(30) Foreign Application Priority Data
Nov. 25, 2021 (KR) 10-2021-0164907
Dec. 16, 2021 (KR) 10-2021-0181007

(51) Int. Cl. H01S 5/183; H01S 5/042; H01S 5/40; H01S 5/42

(52) U.S. Cl. CPC H01S 5/18361; H01S 5/0425; H01S 5/4018; H01S 5/423; H01S 5/18311

(57) ABSTRACT

Disclosed is a VCSEL array having m rows and n columns. Each of VCSELs includes a first substrate doped with a first polar dopant, a first reflective layer comprising a plurality of distributed Bragg reflector (DBR) pairs, a second reflective layer comprising a plurality of DBR pairs, a cavity layer positioned between the first reflective layer and the second reflective layer, an oxide layer positioned between the cavity layer and the first or second reflective layer to determine characteristics of a to-be-output laser and a diameter of an opening, an insulating layer coated on the second reflective layer to protect the first reflective layer, the second reflective layer, the cavity layer, and the oxide layer from the outside, a first electrode electrically connected to the second reflective layer, supplying power to the second reflective layer, and a second electrode positioned at a lower end of the first substrate.

### CROSS-REFERENCE TO RELATED APPLICATION(S)

This application is a divisional application of U.S. patent application Ser. No. 17/989,803 filed on Nov. 18, 2022, which claims priority to Korean Patent Application Nos. 10-2021-0164907, filed on Nov. 25, 2021, and 10-2021-0181007, filed on Dec. 16, 2021, in the Korean Intellectual Property Office, the disclosures of which are incorporated by reference herein in their entireties.

### STATEMENT OF GOVERNMENTAL SUPPORT

This patent application is the results of research that was carried out by the support (a unique project number: 2410012990, a detailed project number: 20018154, a project name: Development of Multi-Axis Assembly System for Curved Free Form Electronics) of Korea Evaluation Institute of Industrial Technology by the finances of the government of the Republic of Korea (Ministry of Trade, Industry and Energy) in 2025.

This patent application is the results of research that was carried out by the support (a unique project number: 2410014173, a detailed project number: 25421386, a project name: Development of Semiconductor Heater Module for the Dryer of Battery Electrode Coating Process) of Korea Evaluation Institute of Industrial Technology by the finances of the government of the Republic of Korea (Ministry of Trade, Industry and Energy) in 2025.

### TECHNICAL FIELD

An embodiment of the present disclosure relates to a VCSEL array having improved properties of output light.

### DISCUSSION OF RELATED ART

The content described in this section merely provides background information for the present embodiment and does not constitute the prior art.

In general, semiconductor laser diodes include edge-emitting laser diode (hereinafter abbreviated as “EEL”) and vertical cavity surface emitting laser (hereinafter abbreviated as “VCSEL”). The EEL has a resonance structure forming a direction parallel to the stacking surface of the element, thereby oscillating the laser beam in a direction parallel to the stacking surface. The VCSEL has a resonance structure perpendicular to the device's stacking surface, thereby oscillating the laser beam in a direction perpendicular to the stacked surface of the element.

Compared to EEL, VCSEL has a shorter optical gain length, enabling low-power realization and high-density integration, which is advantageous for mass production. Further, the VCSEL may oscillate a laser beam in a single longitudinal mode and can be tested on a wafer. Furthermore, the VCSEL is capable of high-speed modulation and can oscillate a circular beam so that it can be easily coupled with an optical fiber and implemented as a two-dimensional surface array.

VCSEL has been mainly used as light sources in optical devices in optical communication, optical interconnection, optical pickup, and the like. However, in recent years, the range of use of VCSELs has been expanded to the area of light sources or sensors in image-forming apparatuses such as light detection and ranging (LiDAR), facial recognition, motion recognition, augmented reality (AR) or virtual reality (VR) devices.

In order for the VCSEL to operate in the area of the light source or sensor in the image-forming apparatus, it must be able to output light with precise optical properties. VCSEL is ideal for pulse driving, but in reality, ideal pulse driving is impossible by the connection between respective devices or by the resistance (R), inductance (L), and capacitance (C) that inevitably occur within each device. Accordingly, it is necessary to minimize the adverse effect caused by the RLC so that the VCSEL may perform pulse driving as much as possible.

### SUMMARY

One embodiment of the present disclosure provides a VCSEL package comprising a GaN FET driving driver and having improved properties of output light by minimizing the effects of resistance, inductance, and capacitance inevitably caused in the package.

One embodiment of the present disclosure provides a VCSEL array that has a common anode structure or a common cathode structure, thereby facilitating operation and improving the quality of output light.

According to an aspect, the present disclosure may provide a VCSEL array having m rows and n columns, wherein VCSELs are connected in series or parallel in each column, and the VCSELs comprises: a first substrate doped with a first polar dopant; a first reflective layer positioned on the first substrate and comprising a plurality of distributed Bragg reflector (DBR) pairs; a second reflective layer positioned above the first reflective layer and comprising a plurality of DBR pairs; a cavity layer positioned between the first reflective layer and the second reflective layer, wherein a hole generated in one of the first reflective layer and the second reflective layer and an electron generated in the other are recombined; an oxide layer positioned between the cavity layer and the first or second reflective layer to determine characteristics of a to-be-output laser and a diameter of an opening; an insulating layer coated on the second reflective layer to protect the first reflective layer, the second reflective layer, the cavity layer, and the oxide layer from the outside; a first electrode electrically connected to the second reflective layer, supplying power to the second reflective layer; and a second electrode positioned at a lower end of the first substrate, supplying power to the first reflective layer.

The second reflective layer may be implemented as a semiconductor layer doped with a dopant having a polarity different from that of the first reflective layer.

The insulating layer may comprise a hole so that the second reflective layer and the first electrode may be electrically connected.

The first substrate may be doped with an n-type dopant.

The first substrate may be doped with a p-type dopant.

According to an aspect, the present disclosure may provide a VCSEL array having m rows and n columns, wherein VCSELs are connected in series or parallel in each column, and the VCSELs comprises: a first substrate doped with a first polar dopant; a first reflective layer positioned on the first substrate and comprising a plurality of distributed Bragg reflector (DBR) pairs; a second reflective layer positioned above the first reflective layer and comprising a plurality of DBR pairs; a cavity layer positioned between the first reflective layer and the second reflective layer, wherein a hole generated in one of the first reflective layer and the second reflective layer and an electron generated in the other are recombined; an oxide layer positioned between the cavity layer and the first or second reflective layer to determine characteristics of a to-be-output laser and a diameter of an opening; an insulating layer coated on the second reflective layer to protect the first reflective layer, the second reflective layer, the cavity layer, and the oxide layer from the outside; a first electrode electrically connected to the second reflective layer, supplying power to the second reflective layer; and a second electrode positioned at a lower end of the first substrate, supplying power to the first reflective layer.

According to an aspect, the present disclosure may provide a VCSEL array having m rows and n columns, wherein VCSELs are connected in series or parallel in each column, and each of VCSELs comprises: an undoped substrate; a first substrate positioned on the undoped substrate and doped with a first polar dopant; a first reflective layer positioned on the first substrate and comprising a plurality of DBR pairs; a second reflective layer positioned above the first reflective layer and comprising a plurality of DBR pairs; a cavity layer positioned between the first reflective layer and the second reflective layer, wherein a hole generated in one of the first reflective layer and the second reflective layer and an electron generated in the other are recombined; an oxide layer positioned between the cavity layer and the first or second reflective layer to determine characteristics of a to-be-output laser and a diameter of an opening; a first electrode electrically connected to the second reflective layer, supplying power to the second reflective layer; a second electrode positioned on the remaining area on the first substrate, where the first reflective layer is not positioned, supplying power to the first reflective layer; and an insulating layer coated on the second reflective layer and the second electrode to protect the first reflective layer, the second reflective layer, the cavity layer, the oxide layer, and the second electrode from the outside.

The insulating layer may comprise a first hole so that the second reflective layer and the first electrode may be electrically connected.

The insulating layer may comprise a second hole so that the second electrode may be exposed to the outside.

The predetermined VCSEL of a column may be isolated from the VCSEL of another adjacent column.

According to an aspect, the present disclosure may provide a VCSEL array having m rows and n columns, wherein VCSELs are connected in series or parallel in each column, and each of VCSELs comprises: an undoped substrate; a first substrate positioned on the undoped substrate and doped with a first polar dopant; a first reflective layer positioned on the first substrate and comprising a plurality of DBR pairs; a second reflective layer positioned above the first reflective layer and comprising a plurality of DBR pairs; a cavity layer positioned between the first reflective layer and the second reflective layer, wherein a hole generated in one of the first reflective layer and the second reflective layer and an electron generated in the other are recombined; an oxide layer positioned between the cavity layer and the first or second reflective layer to determine characteristics of a to-be-output laser and a diameter of an opening; a first electrode electrically connected to the second reflective layer, supplying power to the second reflective layer; a second electrode positioned on the remaining area on the first substrate, where the first reflective layer is not positioned, supplying power to the first reflective layer; and an insulating layer coated on the second reflective layer and the second electrode to protect the first reflective layer, the second reflective layer, the cavity layer, the oxide layer, and the second electrode from the outside.

According to an aspect, the present disclosure may provide a VCSEL array having m rows and n columns, wherein VCSELs are connected in series or parallel in each column, and each of VCSELs comprises: an undoped substrate; a first reflective layer positioned on the undoped substrate and comprising a plurality of DBR pairs; a first substrate formed in one DBR pair of the first reflective layer; a second reflective layer positioned above the first reflective layer and comprising a plurality of DBR pairs; a cavity layer positioned between the first reflective layer and the second reflective layer, wherein a hole generated in one of the first reflective layer and the second reflective layer and an electron generated in the other are recombined; an oxide layer positioned between the cavity layer and the first or second reflective layer to determine characteristics of a to-be-output laser and a diameter of an opening;

a first electrode electrically connected to the second reflective layer, supplying power to the second reflective layer; a second electrode electrically connected to the first substrate, supplying power to the first reflective layer; and an insulating layer coated on the second reflective layer and the second electrode to protect the first reflective layer, the second reflective layer, the cavity layer, the oxide layer, and the second electrode from the outside.

The first substrate may have a mesa structure.

The insulating layer may comprise a hole so that the second electrode and the first substrate may be electrically connected.

The second electrode may be disposed on the mesa structure of the first substrate to be electrically connected to the first substrate.

According to an aspect, the present disclosure may provide a VCSEL array having m rows and n columns, wherein VCSELs are connected in series or parallel in each column, and each of VCSELs comprises: an undoped substrate; a first reflective layer positioned on the undoped substrate and comprising a plurality of DBR pairs; a first substrate formed in one DBR pair of the first reflective layer; a second reflective layer positioned above the first reflective layer and comprising a plurality of DBR pairs; a cavity layer positioned between the first reflective layer and the second reflective layer, wherein a hole generated in one of the first reflective layer and the second reflective layer and an electron generated in the other are recombined; an oxide layer positioned between the cavity layer and the first or second reflective layer to determine characteristics of a to-be-output laser and a diameter of an opening;

a first electrode electrically connected to the second reflective layer, supplying power to the second reflective layer; a second electrode electrically connected to the first substrate, supplying power to the first reflective layer; and an insulating layer coated on the second reflective layer and the second electrode to protect the first reflective layer, the second reflective layer, the cavity layer, the oxide layer, and the second electrode from the outside.

As described above, according to one aspect of the present embodiment, there is an advantage in that the characteristics of output light can be improved by minimizing the effects of resistance, inductance, and capacitance inevitably caused in the package.

Further, according to one aspect of the present embodiment, it has a common anode structure or a common cathode structure, thereby facilitating operation and improving the quality of output light.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view of a VCSEL package according to an embodiment of the present disclosure;

FIG. 2A and FIG. 2B are views illustrating structures of a VCSEL array and a switch according to the first and second embodiments of the present disclosure, respectively;

FIG. 3A and FIG. 3B are circuit diagrams between a switch and a plurality of VCSELs according to the first and second embodiments of the present disclosure, respectively;

FIG. 4 is a view illustrating a first structure of a VCSEL according to an embodiment of the present disclosure;

FIG. 5 is a view illustrating a second structure of a VCSEL according to an embodiment of the present disclosure;

FIG. 6 is a view illustrating a modified embodiment of a VCSEL array and a switch structure according to the first and second embodiments of the present disclosure;

FIG. 7 is a view illustrating the structure of a VCSEL array and a switch according to a third embodiment of the present disclosure;

FIGS. 8A and 8B are views illustrating a first structure of a VCSEL according to a third embodiment of the present disclosure;

FIGS. 9A and 9B are views illustrating a second structure of a VCSEL according to a third embodiment of the present disclosure;

FIGS. 10A and 10B are views illustrating a third structure of a VCSEL according to a third embodiment of the present disclosure;

FIG. 11 is a circuit diagram between a switch and a plurality of VCSELs according to a fourth embodiment of the present disclosure;

FIG. 12 is a schematic view illustrating the structure of a VCSEL according to a fourth embodiment of the present disclosure; and

FIG. 13 is a plan view illustrating a VCSEL according to an embodiment of the present disclosure.

### DETAILED DESCRIPTION

Various modifications may be made to the present disclosure, and various embodiments may be included. Accordingly, specific embodiments are illustrated in the drawings and described in detail. However, the present disclosure is not intended to be limited to specific embodiments, and it should be understood to include all modifications, equivalents and substitutes included in the spirit and scope of the present disclosure. In describing each figure, like reference numerals have been used for like elements.

Terms such as first, second, A, and B may be used to describe various elements, but the elements should not be limited by the terms. The above terms are used only for the purpose of distinguishing one component from another. For example, a first component may be referred to as a second component, and similarly, a second component may also be referred to as a first component without departing from the scope of the present disclosure. The term “and/or” includes a combination of a plurality of related described items or any of a plurality of related described items.

When a component is referred to as being “coupled” or “connected” to another component, it is understood that the component may be directly coupled or connected to another component, but other components may exist in therebetween. On the other hand, when it is said that a component is “directly coupled” or “directly connected” to another component, it should be understood that no other component is present in the middle.

The terms used in the present application are only used to describe specific embodiments and are not intended to limit the present disclosure. The singular expression includes the plural expression unless the context clearly dictates otherwise. It should be understood that terms such as “comprise” or “have” in the present application do not preclude the possibility of addition or existence of features, numbers, steps, operations, components, parts, or combinations thereof described in the specification in advance.

Unless defined otherwise, all terms used herein, including technical and scientific terms, have the same meaning as commonly understood by one of ordinary skill in the art to which this invention belongs.

Terms such as those defined in a commonly used dictionary should be interpreted as having a meaning consistent with the meaning in the context of the related art and should not be interpreted in an ideal or excessively formal meaning unless explicitly defined in the present application.

Further, each configuration, step, process or method included in each embodiment of the present disclosure may be shared within a range that does not technically contradict each other.

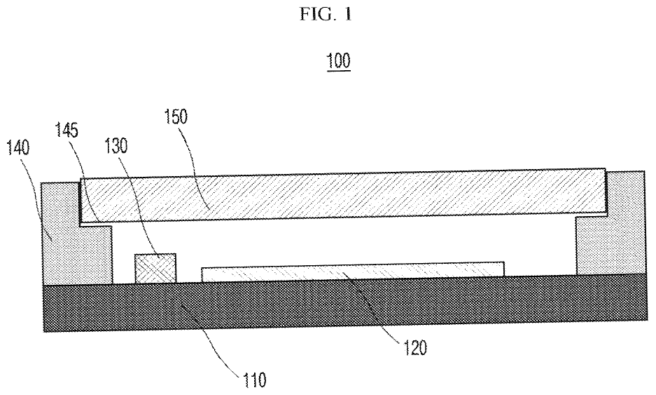

FIG. 1 is a cross-sectional view of a VCSEL package according to an embodiment of the present disclosure.

Referring to FIG. 1, the VCSEL package 100, according to an embodiment of the present disclosure, comprises a support substrate 110, a VCSEL array 120, a switch 130, a housing 140, and a lens 150.

The support substrate 110 supports each component in the VCSEL package 100.

The VCSEL array 120 is an optical device in which a plurality of VCSELs are arranged in an array form, and vertically output light (or laser) having a predetermined intensity or higher. The VCSEL array 120 comprises a plurality of VCSELs, typically tens to hundreds of VCSELs, in order to output light of a predetermined intensity or higher.

The switch 130 controls whether a preset number of VCSELs in the VCSEL array 120 are operated. A plurality of switches 130 are included in the VCSEL package 100 in order to control the operation of the plurality of VCSELs. For example, when the VCSEL array 120 is implemented with m*n VCSELs, n switches 130 may be included to control the operation of the VCSELs in respective columns.

The switch 130 controls whether to supply power to the VCSELs (operation of VCSELs). It controls according to whether a power signal is applied from the outside. However, as described above, since the switch 130 controls operation by controlling whether a power signal is applied to the n VCSELs, power must be supplied to all of the n VCSELs. Accordingly, the switch 130 may be implemented as a gallium nitride (GaN) field effect transistor (FET) (hereinafter abbreviated as “GaN FET”). The GaN FET may have better current transfer capacity, support a relatively higher voltage, and provide a faster switching speed than a conventional general FET. Accordingly, the switch 130 may be implemented with a GaN FET to control the operation of the plurality of VCSELs.

The switch 130 is wire-bonded with the VCSEL array to control VCSELs in the VCSEL array 120. However, as the distance between the two elements 120 and 130 increases, the resistance, inductance, or capacitance increases, so the operating characteristics of the VCSELs may deteriorate. Accordingly, the switch 130 is disposed adjacent to (within a preset radius) the VCSEL array 120 in the package 100, thereby preventing an increase in resistance, inductance, or capacitance due to a separation distance.

The housing 140 protects the VCSEL array 120 and the switch 130 from external forces, and the lens 150 is disposed thereon. The housing 140 is disposed on the outermost side of the support substrate 110 so that the VCSEL array 120 and the switch 130 may be disposed inside the package 100.

The housing 140 is provided with a step 145, and the lens 150 is disposed on the step 145 to be fixed.

The lens 150 is disposed in front (upper) in the direction in which the VCSEL array 120 outputs light and converts the path of the light output from the VCSEL array 120.

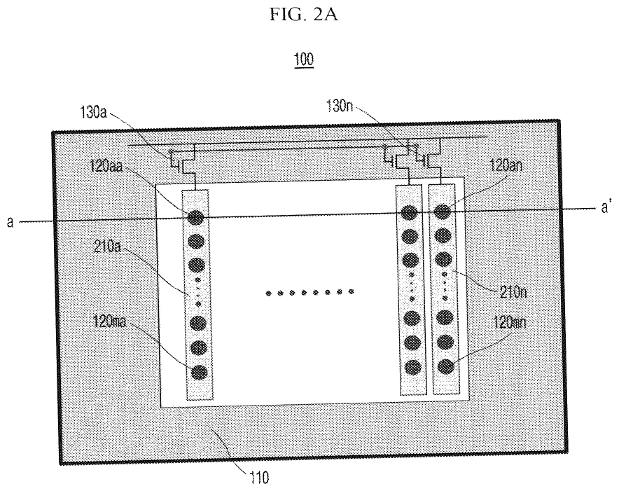

The VCSEL array 120 and the switch 130 have structures to be described later with reference to FIGS. 2, 3, 4, 5, 6, 7, 8, 9, 10, and 11, so the VCSEL package 100 may output light having excellent quality.

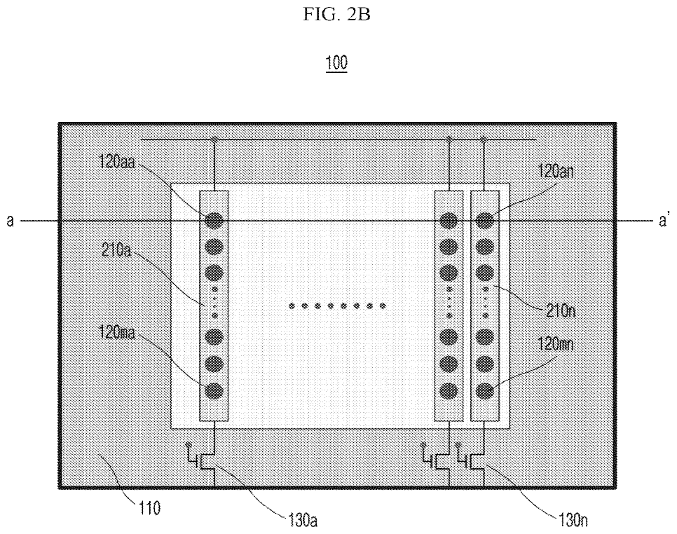

FIG. 2A is a view illustrating a structure of a VCSEL array and a switch according to the first embodiment of the present disclosure. FIG. 3A is a circuit diagram between a switch and a plurality of VCSELs according to the first embodiment of the present disclosure.

Referring to FIG. 2A, the VCSEL array 120 is implemented with m*n VCSELs 120aa to 120mn. The VCSELs 120aa to 120ma, . . . 120an to 120mn in columns are connected to the common electrodes 210a to 210n, and the switches 130a to 130n are connected (wire bonding) to common electrodes, thereby controlling the operation of the VCSELs in columns. Since the VCSELs in each column are isolated and do not affect each other, the switches 130a to 130n are included as much as the number of columns in the VCSEL array 120, as shown in FIG. 2A and control the operation of the VCSELs contained in each column collectively or individually.

As shown in FIG. 3A, the VCSELs of each column are connected in parallel, and each VCSEL (connected in parallel) is connected to the switch 130 on one side and a ground terminal (not shown) on the other side. Accordingly, when the switch 130 is short-circuited, and power is supplied to one side of the VCSELs, all of the VCSELs in the corresponding column may operate.

Since the VCSELs of each column are connected in parallel, a significant amount of current must be able to be transferred to operate the VCSELs of the corresponding column. Accordingly, as the switch 130 is implemented as a GaN FET, this issue may be addressed.

The VCSEL array 120, according to the first embodiment described with reference to FIGS. 2A and 3A, has a common cathode structure. The common cathode structure refers to a form in which an n-type substrate and an n-type electrode are disposed at one position of the substrate in a VCSEL array, and the cathode is commonly used. In a VCSEL array having a common cathode structure, an operating voltage is individually applied to VCSELs between channels, and a single driver field effect transistor (FET) is commonly connected to the VCSELs between channels to control on/off. Meanwhile, the VCSEL array 120 may have a structure, as shown in FIGS. 2B and 3B.

FIG. 2B is a view illustrating a structure of a VCSEL array and a switch according to the second embodiment of the present disclosure. FIG. 3B is a circuit diagram between a switch and a plurality of VCSELs according to the second embodiment of the present disclosure.

As shown in FIG. 2B, the VCSEL array 120 is implemented with m*n VCSELs 120aa to 120mn. An operating voltage is applied to one terminal of the VCSELs 120aa to 120ma, . . . 120an to 120mn of columns, and the switch 130 is connected to the other terminal to control whether the operation is performed. At this time, one terminal of columns in the VCSEL array is common to each other, and the same operating voltage is applied to the VCSELs of all columns. It is determined whether the VCSELs of a specific column operate according to whether the switch 130 connected to the other terminals of columns in the VCSEL array is turned on or off.

As shown in FIG. 3B, each column has VCSELs connected in parallel, an anode of VCSEL is disposed toward one terminal of each column, and a cathode of VCSEL 120 is disposed toward the switch 130. Accordingly, the anode of all VCSELs in the VCSEL array 100 is common, and the VCSEL array 100 has a common anode structure.

The anode of the VCSELs in columns is common, and the following effects occur as different switches 130 are connected to columns. One switch is not connected to all columns, but different switches 130 are connected to columns. Thus, even if another second column operates while one first column is operating as in the prior art, the second column is the first column, and the second column is unaffected by the switch 130 in the first column. Accordingly, even if the same operating voltage as that of the first column (not added by the magnitude of the reverse voltage) is applied to the second column, the second column may also operate smoothly.

Further, a continuous reverse voltage is not applied to non-operating columns. Accordingly, unnecessary shortening of the lifespan of the VCSELs in the non-operating column may also be prevented.

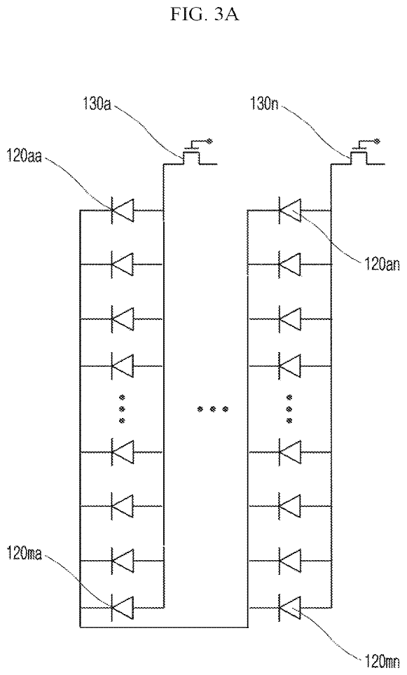

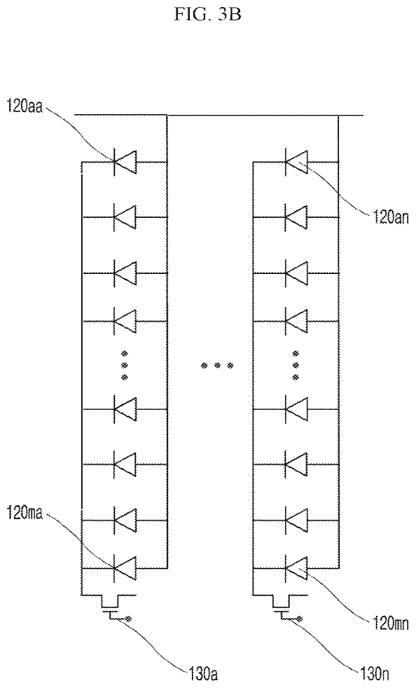

Each VCSEL in the VCSEL array 120 has the structure shown in FIG. 4 or FIG. 5.

FIG. 4 is a view illustrating a first structure of a VCSEL according to an embodiment of the present disclosure.

Referring to FIG. 4, a first electrode 210, an n-type substrate 410, a first reflective layer 420, a cavity layer 430, an oxide layer 440, a second reflective layer 450, an insulating layer 460, and a second electrode are included.

The n-type substrate 410 allows the first reflective layer 420 to grow on its top. The n-type substrate 410 is doped with a dopant having the same polarity as the first reflective layer 420 so that the first reflective layer 420 can grow on its top.

The first reflective layer 420 may be implemented as an n-type semiconductor layer doped with an n-type dopant and with various components such as AlGaAs, which is a semiconductor material including Al. The first reflective layer 420 includes a plurality of DBR pairs. The DBR pair is implemented as a plurality of pairs in which one pair comprises a high aluminum composition layer comprising a high aluminum (Al) percentage of 85 to 100% and a low aluminum composition layer comprising a low aluminum percentage of 0 to 20%. The first reflective layer 420 includes more DBR pairs than the second reflective layer 450 to have relatively higher reflectivity. Accordingly, the light or laser oscillated from the cavity layer 430 is oscillated in the direction of the second reflective layer 450 having a low reflectivity due to a relatively small number of pairs.

The cavity layer 430 is a layer in which holes generated in the second reflective layer 450 and electrons generated in the first reflective layer 420 meet and recombine so that light is generated by recombining electrons and holes. The cavity layer 430 may include a single quantum well (SQW) structure or a multiple quantum well (MQW) structure having a plurality of quantum well layers. When the multi-quantum well structure is included, the cavity layer 430 has a structure in which well layers (not shown) and barrier layers (not shown) having different energy bands are alternately stacked one or more times. The well layer (not shown)/barrier layer (not shown) of the cavity layer 430 may be formed of InGaAs/AlGaAs, InGaAs/GaAs, InGaAs/GaAs, or GaAs/AlGaAs.

An oxidized portion of a certain length is formed on the oxide layer 440 through an oxidation process, and the length of the oxidized portion in the oxide layer 440 determines the characteristics of the output laser and the diameter of the opening. The oxide layer 440 is formed of aluminum (Al) having a higher concentration than the first reflective layer 420 and the second reflective layer 450. The higher the aluminum concentration, the higher the rate of oxidation. The oxide layer 440 is formed with a relatively higher aluminum concentration than both the reflective layer 420 and 450, so oxidation may be selectively performed during subsequent oxidation. For example, the oxide layer 440 may be implemented with AlGaAs having an Al ratio of 98% or more, and each of the reflective layers, 420 and 450, may be implemented with AlGaAs having an Al ratio of 0% to 100%. Although it is illustrated in FIG. 2 that the oxide layer 440 is formed adjacent to the second reflective layer 450, the present disclosure is not limited thereto. It may be formed at a position adjacent to the first reflective layer 420 or at both positions adjacent to the first reflective layer 420 and the second reflective layer 450.

The second reflective layer 450 may be implemented as a p-type semiconductor layer doped with a p-type dopant and may be formed of AlGaAs, which is a semiconductor material including Al. The second reflective layer 450 also includes a plurality of DBR pairs. However, as described above, it includes a relatively smaller number of DBR pairs than the first reflective layer 420. Therefore, it has a relatively low reflectivity. Accordingly, the light or laser oscillated from the cavity layer 430 is oscillated toward the second reflective layer 450 having a low reflectivity due to a relatively small number of pairs.

The insulating layer 460 is coated on the second reflective layer 450 and then cured to fix the VCSEL 120 and prevent exposure to an external environment. The insulating layer 460 may be implemented with SiO2, Si3N4, Al2O3, or the like to perform the above-described operation. The thickness of the insulating layer 460 may be implemented to be about ¼ of the wavelength band of the output light.

The insulating layer 460 includes a hole 465, so the second reflective layer 450 and the first electrode 210 may be electrically connected.

A hole 465 is formed in the insulating layer 460, and a metal pad (not shown) and a first electrode 210 are disposed in the hole 465, so that the second reflective layer 450 and the first electrode 210 are electrically connected to each other. The first electrode 210 is disposed on each of the VCSELs disposed in each column of the VCSEL array to be used as a common electrode and may be exposed to the upper portion of the VCSEL to be connected (e.g., wire bonding) to the switch 130.

Since the first electrode 210 is electrically connected to the second reflective layer 450 implemented as a p-type semiconductor layer through the hole 465, it is implemented as an anode.

The second electrode 470 is formed at the lower end (opposite to the direction in which light is output) of the n-type substrate 410. The second electrode 470 is an electrode commonly used not only for VCSELs in a specific column but also for all VCSELs in the VCSEL array and is electrically connected to the first reflective layer 420 through the n-type substrate 410. Accordingly, the second electrode 470 is implemented as a cathode, and the VCSEL array 120 may have a common cathode structure.

The first electrode 210 is exposed over the VCSELs and implemented as an anode, so the switch is implemented as a p-type GaN FET. However, the size of the p-type GaN FET may be relatively larger, and the driving current may be lower than that of the n-type GaN FET. Accordingly, the VCSELs may be implemented as shown in FIG. 5.

FIG. 5 is a view illustrating a second structure of a VCSEL according to an embodiment of the present disclosure.

Referring to FIG. 5, the VCSEL 120 has a structure similar to that shown in FIG. 4, but a p-type substrate 480 is disposed instead of an n-type substrate 410, and a second reflective layer 450, the cavity layer 430, the oxide layer 440, and the first reflective layer 420 are grown in this order. The first electrode 210 to be electrically connected to the first reflective layer 420 on the upper portion of the VCSEL is implemented as a cathode, and a second electrode 475 implemented as an anode is disposed at the bottom of the p-type substrate 480. Accordingly, the VCSEL array 120 may have a common anode structure.

The first electrode 210 exposed to the upper portion of the VCSEL to be wire-bonded with the switch 130 becomes a cathode. The switch 130 may be implemented as an n-type GaN FET. Since the n-type GaN FET may be implemented as the switch 130 in the VCSEL package 110, the size may be relatively small, and operational efficiency may be improved.

Further, the resistance value of the VCSEL itself becomes small, and the optical properties of the VCSEL may be further improved.

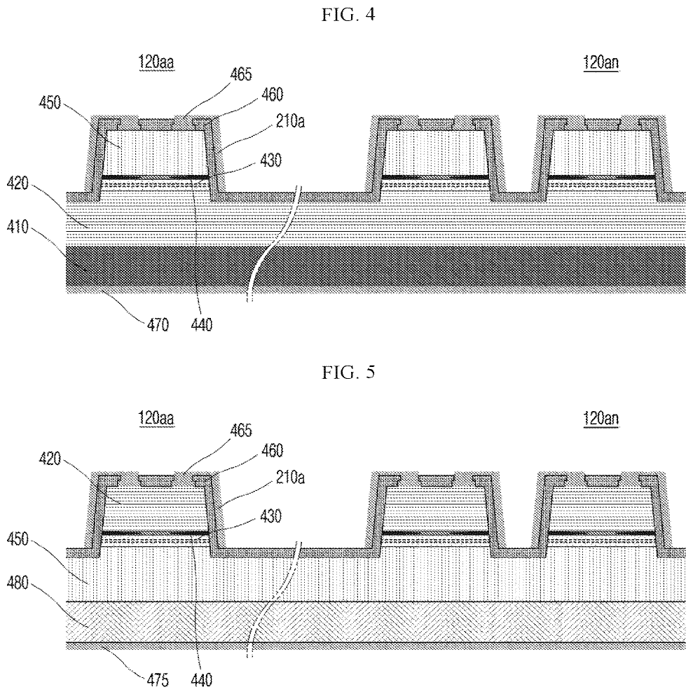

FIG. 6 is a view illustrating a modified embodiment of a VCSEL array and a switch structure according to the first and second embodiments of the present disclosure.

Referring to FIG. 6, the modified embodiment of the VCSEL array, according to the first or second embodiment of the present disclosure, has a structure in which each column is divided into two in the VCSEL array described above with reference to FIG. 2A or 2B and has a form in which a switch is connected to each of the columns. As described with reference to FIG. 3A or 3B, the VCSELs arranged in each column in the VCSEL array have a parallel form.

At this time, as the number of VCSELs connected in parallel increases, the magnitude of the current to be transferred to the corresponding column should increase. Although a GaN FET is used as the switch 130, an allowable amount of current exists. Thus, the allowable amount may be exceeded depending on the number of VCSELs disposed in each column.

Further, although VCSELs are manufactured through the same process, internal resistance values may differ for each VCSEL. Currents must be equally distributed to the VCSELs arranged in each column so that the optical property or lifetimes of each element are not adversely affected. However, as described above, when the internal resistance value of the VCSELs is different since each VCSEL is connected in parallel, more current flows through the VCSEL with a small resistance value, and less current flows through the VCSEL with a larger resistance value.

In order to address this issue, the modified embodiment of the VCSEL array 100, according to the first or second embodiment of the present disclosure, divides the VCSELs arranged in each column into two groups. That is, a VCSEL array with an m*n shape is implemented in the shape of m/2*2n, and 2n switches 130 are included. Accordingly, the amount of current to be transmitted to each column may be relatively reduced, and the deviation of the resistance value may also be reduced due to the decrease in the number.

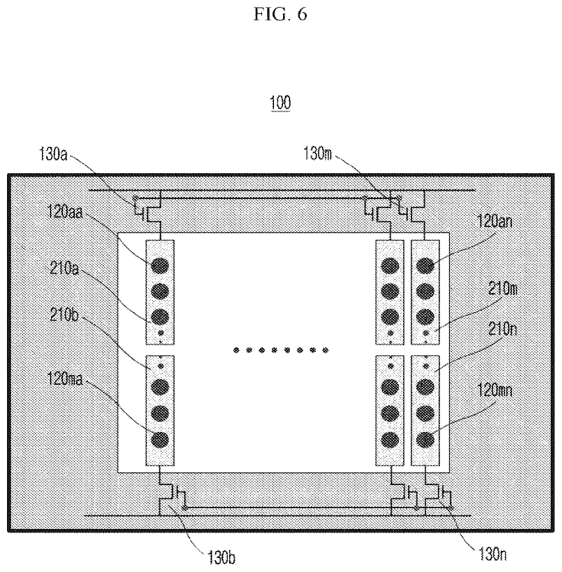

FIG. 7 is a view illustrating the structure of a VCSEL array and a switch according to a third embodiment of the present disclosure.

Referring to FIG. 7, in the VCSEL array 120, according to the third embodiment of the present disclosure, a plurality of VCSELs is implemented in each column like the VCSEL array according to the first embodiment, but it has a shape in which both the first electrode and the second electrode are exposed at the top. Each column in the VCSEL array 120 has the first common electrodes 710a to 710n, and the second common electrodes 720a to 720n. One common electrode is connected to the switch 130, and a position (e.g., 715) of the other common electrode is connected to a ground terminal.

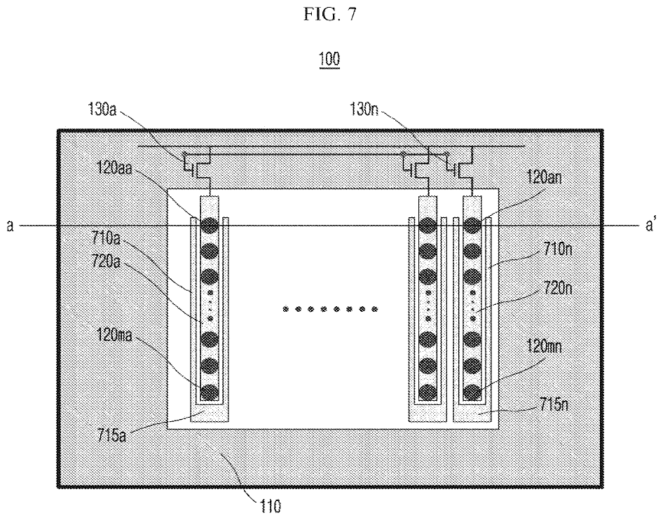

VCSELs having a shape in which all of the electrodes are exposed at the top may be implemented, as shown in FIGS. 8, 9, and 10.

FIG. 8 is a view illustrating the first structure of a VCSEL according to a third embodiment of the present disclosure.

Referring to FIG. 8A, the VCSEL 120, according to the third embodiment of the present disclosure, comprises an n-type substrate 410, a first reflective layer 420, a cavity layer 430, an oxide layer 440, a second reflective layer 450, an insulating layer 460, a first electrode 710, a second electrode 720, and an undoped substrate 810.

In the VCSEL 120, according to the third embodiment of the present disclosure, like the VCSEL according to the first embodiment of the present disclosure, a doped substrate does not support each layer in the VCSEL, but each layer is supported by an undoped substrate 810.

An n-type substrate 410, the first reflective layer 420, the cavity layer 430, the oxide layer 440, the second reflective layer 450, the insulating layer 460, and the second electrode 720 are disposed on the undoped substrate 810.

Meanwhile, on the n-type substrate 410, the first electrode 710 is disposed in the remaining area (e.g., both ends) other than the area in which the first reflective layer 420 is disposed. After the first electrode 710 is disposed on the n-type substrate 410 (after all the first reflective layer 420 and the insulating layer 460 are disposed on the n-type substrate 410), the insulating layer 460 is formed coated. Accordingly, the first electrode 710 is positioned between the n-type substrate 410 and the insulating layer 460.

The first electrode 720 is implemented as a cathode, the second electrode 720 is implemented as an anode, and both electrodes, 710 and 720, are implemented as a common electrode for the VCSELs of each column. The first electrode 710 may be exposed to the outside of the insulating layer 460 at a position 715 and may be connected to a power source. Accordingly, the switch 130 electrically connected (e.g., wire bonding) to the second electrode 720 may be implemented as a p-type GaN FET.

Meanwhile, as shown in FIG. 8B, the VCSEL may be implemented in the same structure as the VCSEL according to the second embodiment. That is, the p-type substrate 480, the second reflective layer 450 and the first electrode 710, the cavity layer 430, the oxide layer 440, the first reflective layer 420, the insulating film 460, and the second electrode 720 may be disposed on the undoped substrate. Accordingly, the polarities of the first electrode 710 and the second electrode 720 are changed, and the switch 130 may be implemented as an n-type GaN FET.

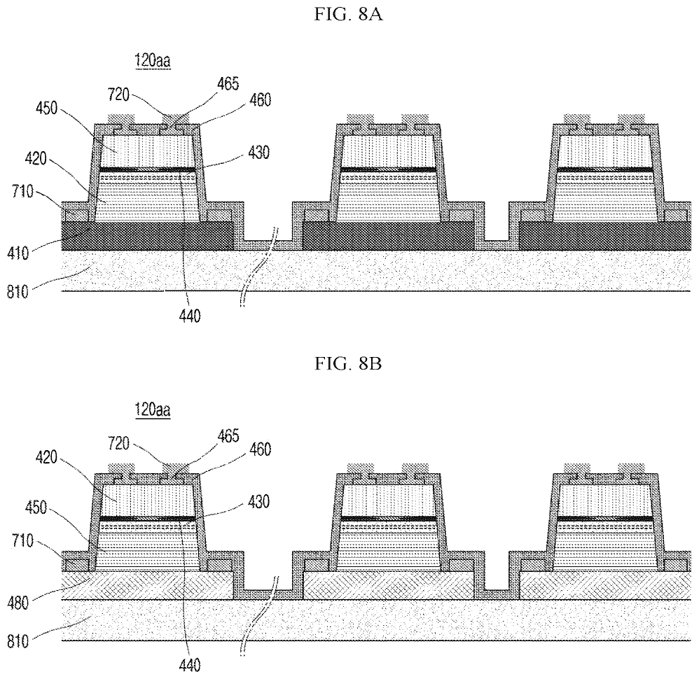

FIG. 9 is a view illustrating a second structure of a VCSEL according to the third embodiment of the present disclosure.

Referring to FIG. 9, the VCSEL 120 having the second structure is similar to that of the VCSEL 120 having the first structure shown in FIG. 8, but an insulating layer 460 comprises an additional hole 465b at a position where the first electrode is disposed. Accordingly, the metal pad and the first electrode 710 are also disposed in the hole 465b, and the first electrode 710 may be exposed to the outside.

According to such a structure, the first electrode in the VCSEL having the second structure may be exposed outside in all of the VCSELs without needing to be exposed outside at one position 715.

Similarly, the VCSEL 120 having the second structure, as shown in FIG. 9B, the order in which layers are disposed on the undoped substrate 810 and the type of the substrate 480 are changed, and the polarity of the first electrode 710 and the second electrode 720 may be changed.

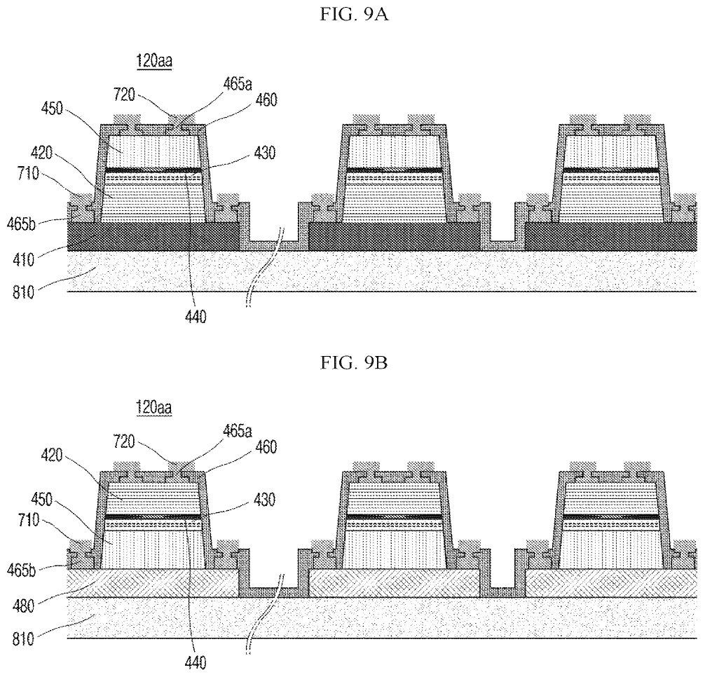

FIG. 10 is a view illustrating a third structure of a VCSEL according to the third embodiment of the present disclosure.

Referring to FIG. 10A, the VCSEL 120 having the third structure may include the n-type substrate 410 on the first reflective layer 420 rather than on the undoped substrate 810. That is, the n-type substrate 410 may be formed in one DRB pair of the first reflective layer 420. Further, etching is performed on one area of both ends of the second reflective layer 450, the cavity layer 440, the oxide layer 430, and the n-type substrate 410, and the VCSEL 120 may have a mesa structure. However, the n-type substrate 410 is etched only partially in the height direction (the direction in which light is output), and a layer is formed on the n-type substrate 410 having a mesa structure.

The insulating layer 460 includes the hole 465a and the hole 465b. The hole 465a allows electrical connection between the second electrode 720 and the second reflective layer 450, and the hole 465b allows an electrical connection between the first electrode 710, the n-type substrate 410, and the first reflective layer 420. Accordingly, the insulating layer 460 allows each of the electrodes 710 and 720 to be directly connected to the reflective layer or to be connected to the reflective layer through the doped substrate.

As it has such a structure, the overall height (direction in which light is output) of the VCSEL 120 may be reduced. A decrease in the height of the VCSEL may bring various advantages in the manufacturing process of the VCSEL, such as a metal lamination process.

Further, power may be applied close to the cavity layer 440 and the oxide layer 430, so the beam profile may be improved, and the lower reflective layer 420 of the n-type substrate 410 may not be doped to minimize light absorption in the reflective layer.

Similarly, the VCSEL 120 having a third structure, as shown in FIG. 10B, the order in which layers are disposed on the undoped substrate 810 and the type of the substrate 480 are changed, and the polarity of the first electrode 710 and the second electrode 720 may be changed.

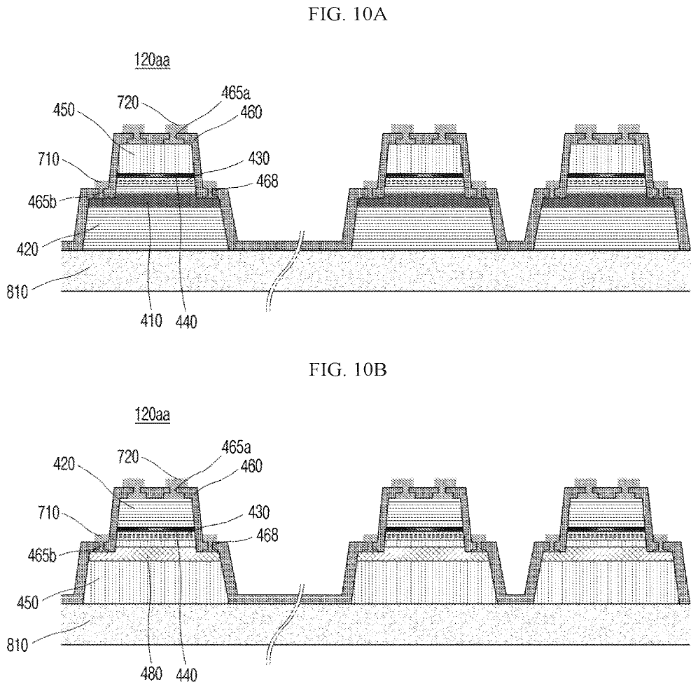

FIG. 11 is a circuit diagram between a switch and a plurality of VCSELs according to the fourth embodiment of the present disclosure.

Referring to FIG. 11, the VCSELs of each column in the VCSEL array 120 may be connected in series rather than in parallel. When the VCSELs of each column are connected in series, unlike the case where they are connected in parallel, there is no need for an excessive current to flow through the array, and it is possible to prevent a change in the amount of current flowing through each VCSEL due to a difference in internal resistance.

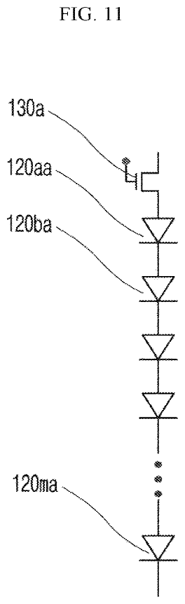

FIG. 12 is a schematic view illustrating the structure of a VCSEL according to the fourth embodiment of the present disclosure.

Referring to FIG. 12, the VCSEL, according to the fourth embodiment of the present disclosure, may have the structure of the VCSEL according to the first to third embodiments of the present disclosure. However, the first electrode of a specific VCSEL in the same column may be connected to the second electrode of another adjacent VCSEL, and the respective VCSELs in the same column may be connected in series.

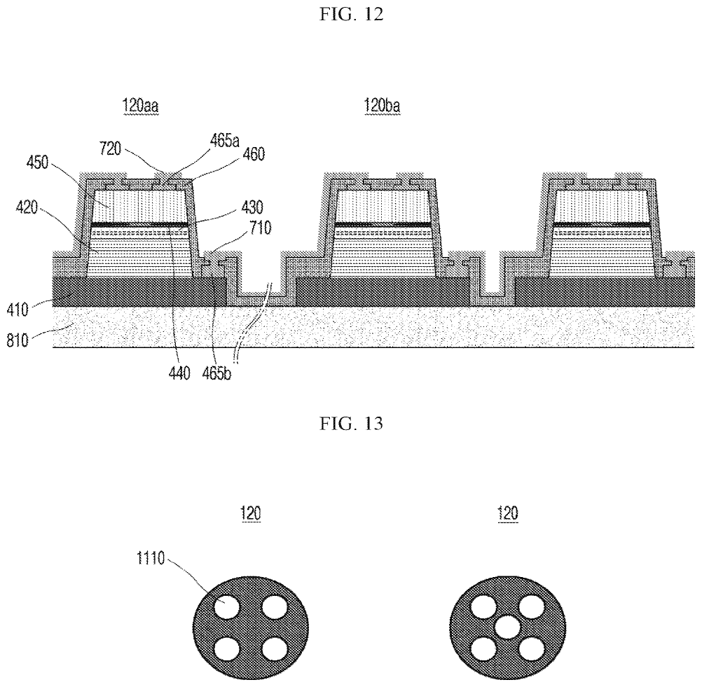

FIG. 13 is a plan view illustrating a VCSEL according to an embodiment of the present disclosure.

Referring to FIG. 13, the VCSEL described with reference to FIGS. 4 and 5, FIGS. 8, 9, and 10, and FIG. 12 has a single mesa. However, the present disclosure is not limited thereto, and each VCSEL may be implemented in a form in which a plurality of mesas 1110 are included in one cell 120. Accordingly, the output amount of the VCSEL array may be improved.

The above description is merely illustrative of the technical idea of this embodiment, and various modifications and variations will be possible without departing from the essential characteristics of the present embodiment by those of ordinary skill in the art to which this embodiment belongs. Accordingly, the present embodiments are intended to explain rather than limit the technical spirit of the present embodiment, and these embodiments do not limit the scope of the technical spirit of the present embodiment. The protection scope of this embodiment should be interpreted by the claims below, and all technical ideas within the scope equivalent thereto should be construed as being included in the scope of the present embodiment.

What is claimed is:

1. A vertical cavity surface emitting laser (VCSEL) array having m rows and n columns, wherein VCSELs are connected in series or parallel in each column, and
wherein each of VCSELs comprises:
a first substrate doped with a first polar dopant;
a first reflective layer comprising a plurality of distributed Bragg reflector (DBR) pairs;
a second reflective layer comprising a plurality of DBR pairs;
a cavity layer positioned between the first reflective layer and the second reflective layer, wherein a hole generated in one of the first reflective layer and the second reflective layer and an electron generated in the other are recombined;
an oxide layer positioned between the cavity layer and the first or second reflective layer to determine characteristics of a to-be-output laser and a diameter of an opening;
an insulating layer coated on the second reflective layer to protect the first reflective layer, the second reflective layer, the cavity layer, and the oxide layer from the outside;
a first electrode electrically connected to the second reflective layer, supplying power to the second reflective layer; and
a second electrode positioned at a lower end of the first substrate, supplying power to the first reflective layer.

2. The VCSEL array of claim 1, wherein the second reflective layer is implemented as a semiconductor layer doped with a dopant having a polarity different from that of the first reflective layer.

3. The VCSEL array of claim 1, wherein the insulating layer comprises a hole so that the second reflective layer and the first electrode may be electrically connected.

4. The VCSEL array of claim 2, wherein the first substrate is doped with an n-type dopant.

5. The VCSEL array of claim 2, wherein the first substrate is doped with a p-type dopant.

6. The VCSEL array of claim 1, wherein the first reflective layer is positioned on the first substrate; and
the second reflective layer is positioned above the first reflective layer.

7. The VCSEL array of claim 1, wherein the second reflective layer is positioned on the first substrate; and
the first reflective layer is positioned above the second reflective layer.
